(19) United States
(12) Patent Application Publication
(10) Pub. No.: US 2026/0150216 A1
(43) Pub. Date: May 28, 2026

(54) SERVER

(71) Applicant: PEGATRON CORPORATION, TAIPEI CITY (TW)

(72) Inventors: Kuo-Chi Chen, Taipei City (TW); Hsin-Kai Chuang, Taipei City (TW)

(73) Assignee: PEGATRON CORPORATION, TAIPEI CITY (TW)

(21) Appl. No.: 19/327,947

(22) Filed: Sep. 12, 2025

(30) Foreign Application Priority Data
Nov. 28, 2024 (TW) 113213007

(51) Int. Cl. H05K 7/14

(52) U.S. Cl. CPC H05K 7/1487

(57) ABSTRACT

The disclosure provides a server including a casing, a first circuit board and a replaceable power module. The first circuit board is disposed within the casing, wherein the first circuit board has at least one of a first electrical connector and a second electrical connector. The replaceable power module is assembled to one side of the casing, and the replaceable power module is electrically connected to the first electrical connector or the second electrical connector.

### CROSS-REFERENCE TO RELATED APPLICATION

This application claims the priority benefit of Taiwan application serial no. 113213007, filed on Nov. 28, 2024. The entirety of the above-mentioned patent application is hereby incorporated by reference herein and made a part of this specification.

### BACKGROUND

### Technical Field

The present disclosure relates to a server.

### Description of Related Art

The power supply method of traditional server design is a single structure; in other words, only one type of power distribution module may be correspondingly configured for servers of different specifications.

Under such limitations, for cabinets with different power distribution systems, only servers matching the power distribution systems may be purchased by the user for use, which requiring payment of enormous costs.

### SUMMARY

The present disclosure provides a server that may be applied to cabinets of different power distribution systems.

A server of the present disclosure includes a casing, a first circuit board, and a replaceable power module. The first circuit board is disposed in the casing, wherein the first circuit board includes at least one of a first electrical connector and a second electrical connector; the replaceable power module is adapted to be assembled to the casing from one side of the casing, and the replaceable power module is adapted to be electrically connected with the first electrical connector or the second electrical connector.

Based on the above, the server of the present disclosure could be applied to cabinets of different power distribution systems since the replaceable power module is replaceable; and therefore the server of the present disclosure has convenience of use.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of a server according to a first embodiment of the present disclosure.

FIG. 2A is an exploded view of the server applying a first type of replaceable power module.

FIG. 2B is a schematic diagram of another viewing angle of the server of FIG. 2A.

FIG. 2C is an assembly view of the server of FIG. 2A.

FIG. 2D is a schematic diagram of another viewing angle of the server of FIG. 2A.

FIG. 3A is an exploded view of the server applying a second type of the replaceable power module.

FIG. 3B is an assembly view of the server of FIG. 3A.

FIG. 3C is a schematic diagram of the power cable assembly in FIG. 3A.

FIG. 3D is a schematic diagram of another viewing angle of the power cable assembly of FIG. 3C.

FIG. 4 is a schematic diagram of the first electrical connector 121 and the second electrical connector 122 together disposed on the first circuit board.

FIG. 5A to FIG. 5C are schematic diagrams of the server with the second type of replaceable power module installed therein being assembled to the cabinet.

### DESCRIPTION OF THE EMBODIMENTS

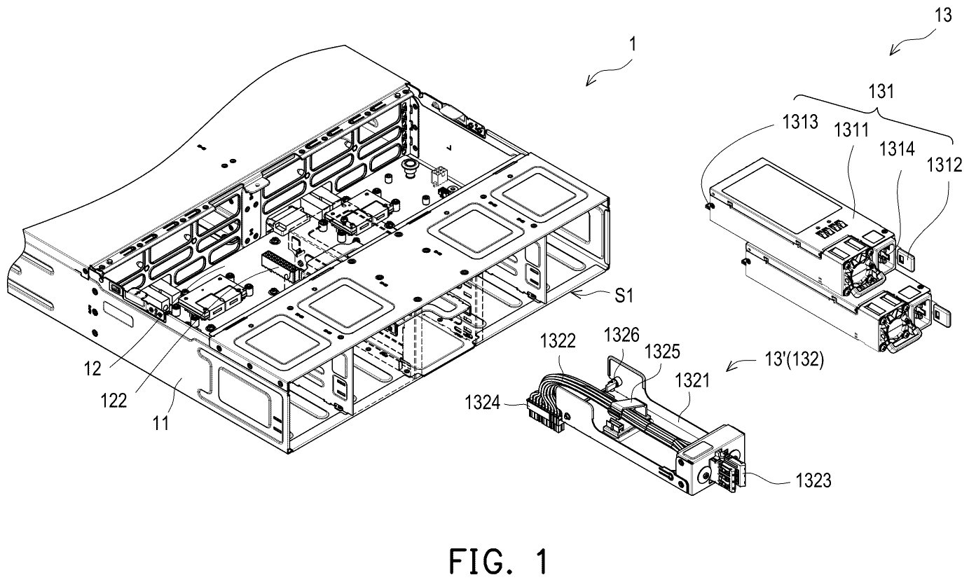

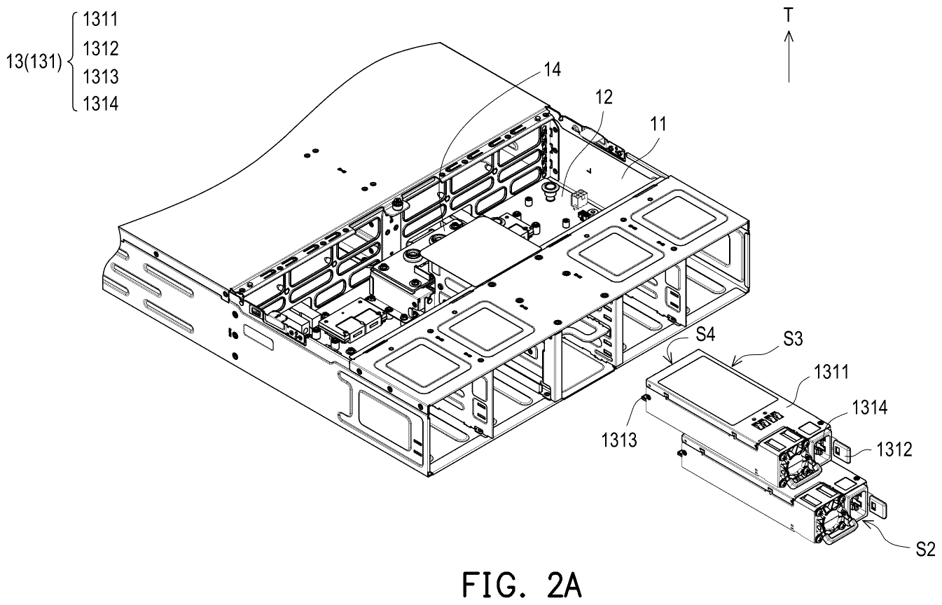

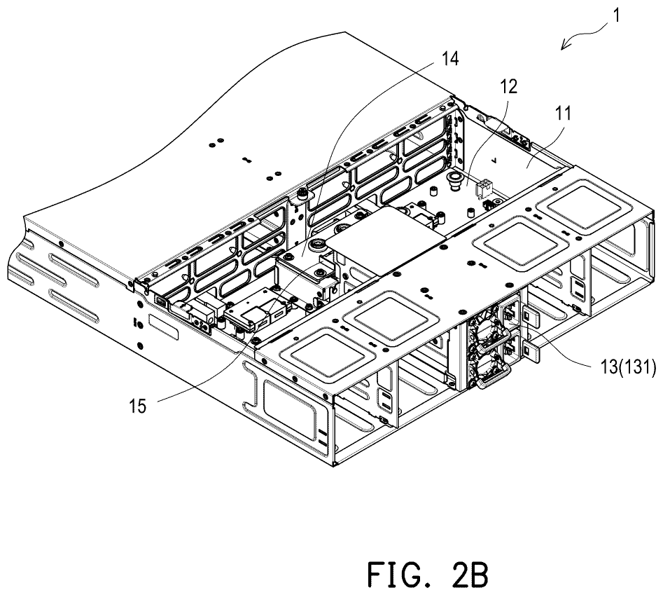

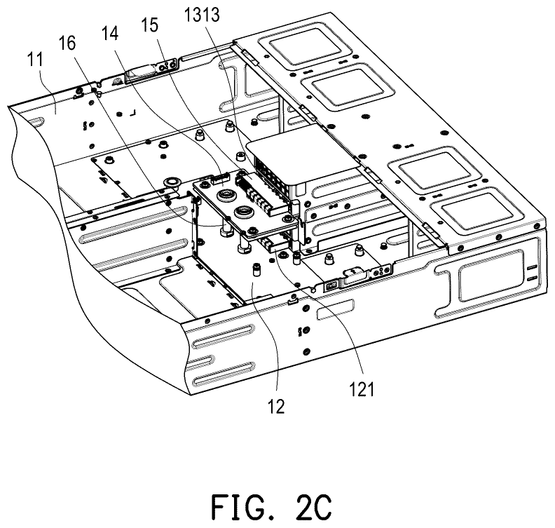

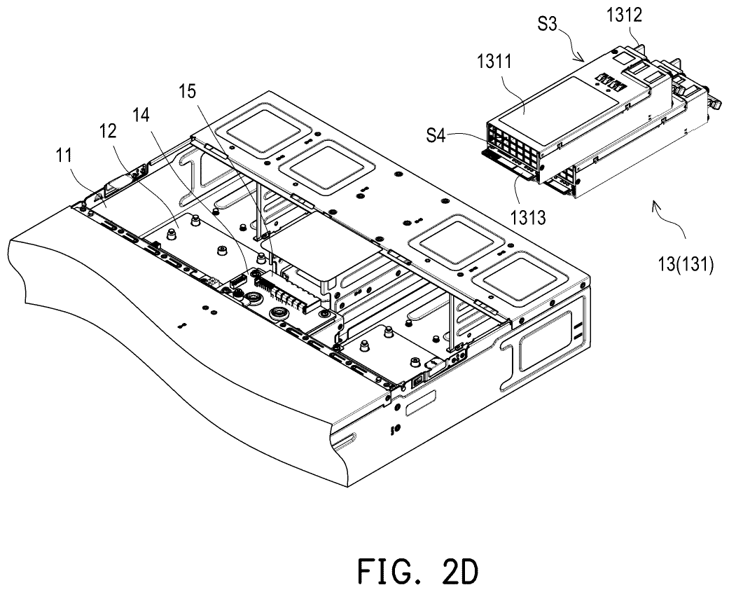

FIG. 1 is a schematic diagram of a server 1 according to a first embodiment of the present disclosure. The server 1 includes a casing 11, a first circuit board 12, at least one electrical connector, and replaceable power modules 13, 13′. The first circuit board 12 is set in the casing 11, and the at least one electrical connector is disposed on the first circuit board 12, wherein the at least one electrical connector includes at least one of a first electrical connector 121 (shown in FIG. 2A) and a second electrical connector 122. The replaceable power modules 13, 13′ may be assembled to the casing 11 from one side S1 of the casing 11, wherein the electrical connection between the replaceable power modules 13, 13′ and the first electrical connector 121 or the second electrical connector 122 may be determined according to the type of the replaceable power modules 13, 13′ inserted into the casing 11. Currently shown in FIG. 1 is the second electrical connector 122.

The aforementioned replaceable power modules 13, 13′ may be a power supply 131 or a power cable assembly 132, and these two types of the replaceable power modules 13, 13′ may share a same casing 11, but are not together placed in the same casing 11.

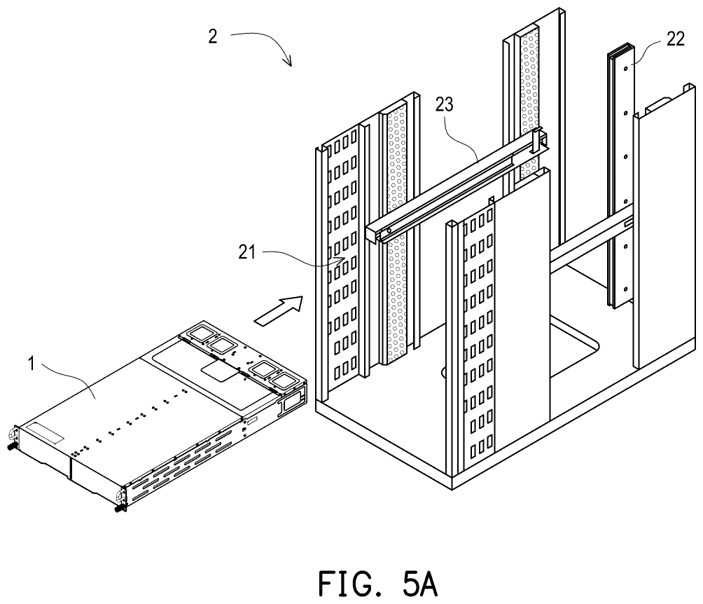

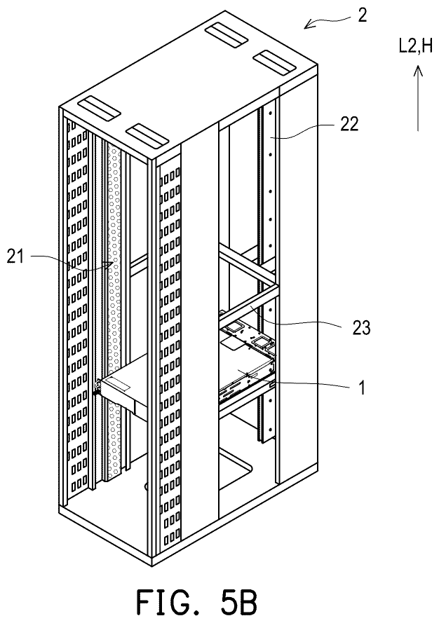

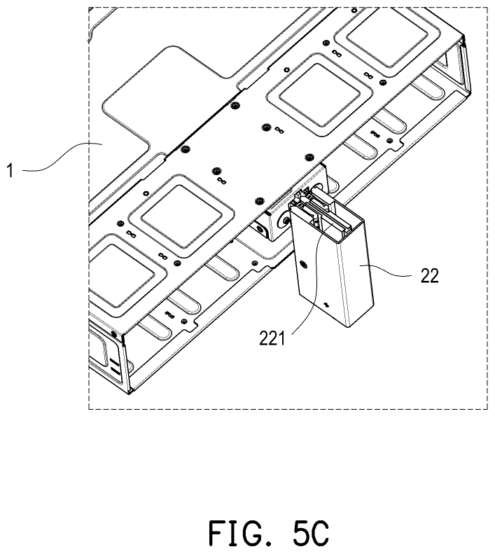

The server 1 may be applied in cabinets 2 (shown in FIG. 5A) having different power distribution systems by replacing the replaceable power modules 13, 13′.

First, using the replaceable power module 13 as a power supply 131 is described as an example.

FIG. 2A is an exploded view of the server 1 applying the first type of replaceable power module 13. FIG. 2B is a schematic diagram of another viewing angle of the server 1 of FIG. 2A. FIG. 2C is an assembly view of the server 1 of FIG. 2A. FIG. 2D is a schematic diagram of another viewing angle of the server 1 of FIG. 2A.

Please refer to FIG. 2A, FIG. 2B, FIG. 2C and FIG. 2D simultaneously, the first type of replaceable power module 13 as a power supply 131 is adapted to be electrically connected with the first electrical connector 121 to supply power to the first circuit board 12. In this embodiment, the power supply 131 includes a main body 1311, a latch 1312, gold fingers 1313 and a plug 1314. The main body 1311 has a first side S2, a second side S3 and a third side S4 connected in sequence, and the third side S4 is opposite to the first side S2. As shown in FIG. 2A, the plug 1314 is disposed on the first side S2 of the main body 1311, the latch 1312 is disposed on the second side S3 of the main body 1311, and the gold fingers 1313 are disposed on the third side S4 of the main body 1311.

The aforementioned first electrical connector 121 is a slot for the gold fingers 1313, and when the power supply 131 is inserted into the casing 11, the gold fingers 1313 may correspondingly insert into the slot, and the power supply 131 may supply power to the first circuit board 12 through the connection of the slot for the gold fingers 1313.

In one embodiment, the latch 1312 is a quick-release structure, which is used to cooperate with the structure of the casing 11 to fix the main body 1311 in the casing 11, or to quickly release the locking with the structure of the casing 11 to withdraw the main body 1311 from the casing 11.

The number of the power supplies 131 in this embodiment may be two, and the two power supplies 131 are stacked along the thickness direction T of the casing 11.

In accordance with the number of power supplies 131 is two, the server 1 may further include a second circuit board 14, a third electrical connector 15 and at least one supporting conductive post 16. The second circuit board 14 is located above the first circuit board 12, the third electrical connector 15 is disposed on the second circuit board 14, and the supporting conductive post 16 is electrically connected between the first circuit board 12 and the second circuit board 14. In one implementation, the supporting conductive post 16 is physically connected between the first circuit board 12 and the second circuit board 14 to support the second circuit board 14, and the first circuit board 12 and the second circuit board 14 achieve electrical connection through the supporting conductive post 16. In this embodiment, the third electrical connector 15 is also implemented as a slot for the gold fingers 1313.

When the two power supplies 131 are assembled into the casing 11, the gold fingers 1313 of the upper and lower stacked power supplies 131 correspondingly insert into the first electrical connector 121 disposed on the first circuit board 12 and the third electrical connector 15 disposed on the third circuit board.

In this way, since the server 1 has the first type of replaceable power module 13 (power supply 131) disposed therein, the server 1 is correspondingly placed in the cabinet 2 of the power distribution system corresponding to the power supply 131 when in use.

When adapting to the cabinet 2 of another power distribution system, the power supply 131 may be pulled out from the casing 11, and replaced with the replaceable power module 13 corresponding to another power distribution system for operation.

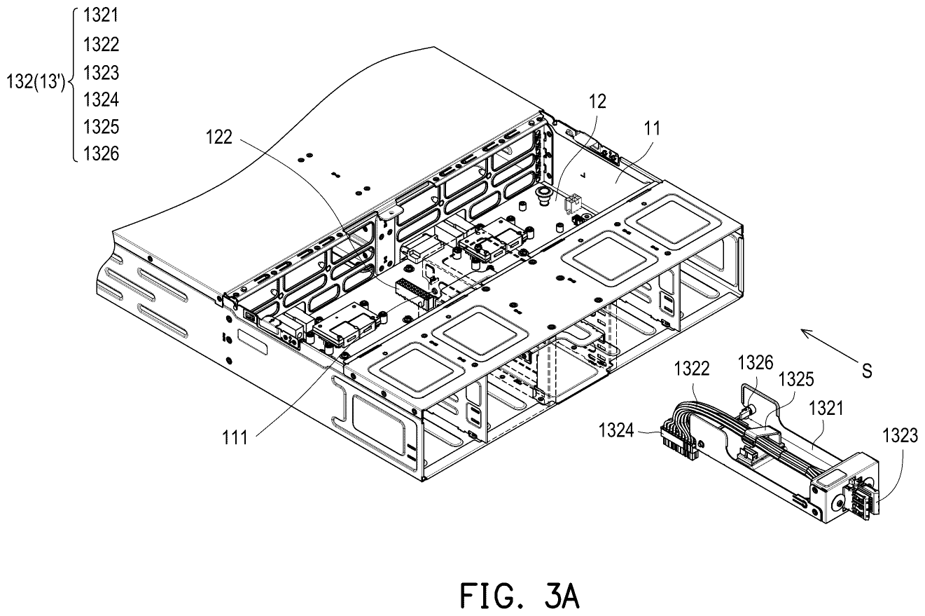

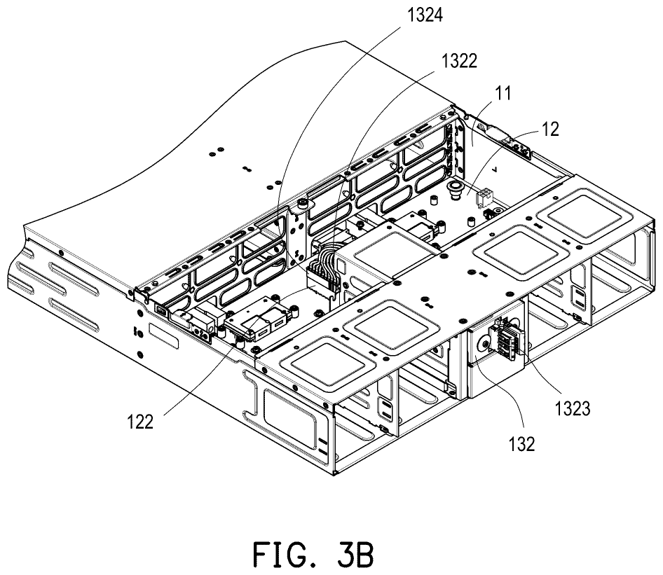

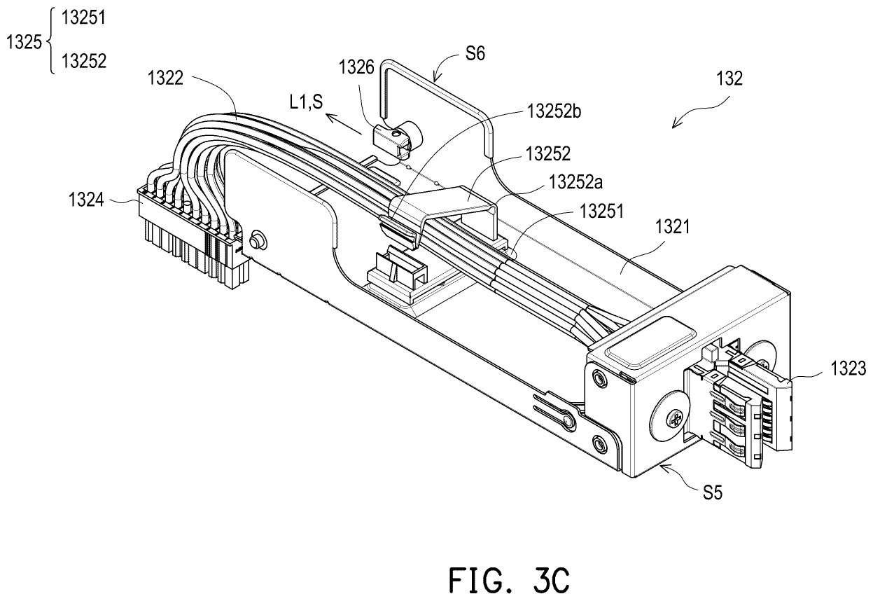

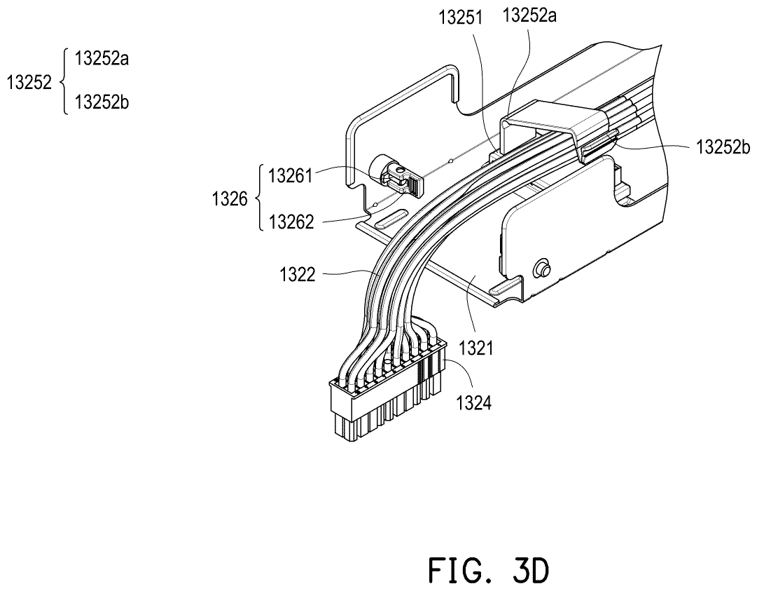

FIG. 3A is an exploded view of the server applying a second type of the replaceable power module 13′, FIG. 3B is an assembly view of the server of FIG. 3A, FIG. 3C is a schematic view of the power cable assembly 132 in FIG. 3A, and FIG. 3D is a schematic view of another viewing angle of the power cable assembly 13′ of FIG. 3C.

Please refer to FIG. 3A, FIG. 3B, FIG. 3C and FIG. 3D simultaneously, the second type of replaceable power module 13′ is a power cable assembly 132 different from the power supply 131.

Specifically, the power cable assembly 132 includes a carrier 1321, a transmission wire 1322 and a fixture 1323. The carrier 1321 may slide relative to the casing 11 to be inserted into the casing 11 or disassembled from the casing 11. The transmission wire 1322 is accommodated in the carrier 1321, one end of the transmission wire 1322 has a fourth electrical connector 1324 adapted to mate with the second electrical connector 122, the fixture 1323 is disposed on one side S5 of the carrier 1321, and the fixture 1323 and the fourth electrical connector 1324 are located on opposite sides of the carrier 1321. The carrier 1321 slides into the casing 11 when the power cable assembly 132 is inserted into the casing 11, and the fourth electrical connector 1324 is mated to the second electrical connector 122.

Following the above, the power cable assembly 132 further includes a cable clip 1325 disposed within the carrier 1321, wherein the cable clip 1325 is adapted to clamp the transmission wire 1322 to limit the position of the transmission wire 1322, avoiding damage to the transmission wire 1322 due to friction with the casing 11 caused by the transmission wire 1322 protruding from the carrier 1321 during the process of the power cable assembly 132 sliding into the casing 11.

The cable clip 1325 includes a base 13251 and a spring arm hook 13252, the base 13251 is fixed within the carrier 1321, and the first end 13252a of the spring arm hook 13252 is fixed to the base 13251, the second end 13252b of the spring arm hook 13252 may engage with the base 13251, and by moving the second end 13252b of the spring arm hook 13252, the engagement between the spring arm hook 13252 and the base 13251 may be released, so that the second end 13252b of the spring arm hook 13252 may pop up with the first end 13252a as the rotation axis and no longer limit the transmission wire 1322.

Please continue to refer to FIG. 3A and FIG. 3C, the above power cable assembly 132 further includes a limiting pin 1326 set on another side S6 of the carrier 1321, the other side S6 of the carrier 1321 is connected to one side S5 of the carrier 1321, and the casing 11 has a positioning hole 111. The power cable assembly 132 slides relative to the casing 11 until the limiting pin 1326 correspondingly engages into the positioning hole 111 to fix the relative position of the power cable assembly 132 and the casing 11.

The above limiting pin 1326 includes a pin 13261 and a handle 13262, wherein the handle 13262 is linked with the pin 13261. During the process of the power cable assembly 132 sliding into the casing 11, the pin 13261 is restricted by the casing 11 and maintains a retracted state to slide relative to the casing 11, at this time the length direction L1 of the handle 13262 is parallel to the sliding direction S of the power cable assembly 132, as shown in FIG. 3C. The pin 13261 slides to the positioning hole 111 and engages into the positioning hole 111, and the position of the power cable assembly 132 within the casing 11 is fixed.

FIG. 3D illustrates changing the angle of the handle 13262 to release the limiting between the pin 13261 and the positioning hole 111. When removing the power cable assembly 132 from the casing 11, the handle 13262 is rotated to change the length protruding from the positioning hole 111, causing the pin 13261 to retract inward to release the limiting with the positioning hole 111. Thus, the power cable assembly 132 is withdrawn from within the casing 11.

Compared to the aforementioned first type of replaceable power module 13 for the power supply 131 which has heavy weight due to many electronic components being provided in the main body 1311, the second type of replaceable power module 13′ only carries the transmission wire 1322 with the carrier 1321, therefore the overall weight of the power cable assembly 132 is lighter than the overall weight of the power supply 131.

Incidentally, when replacing the replaceable power module 13, the first circuit board 12 disposed within the casing 11 may be determined whether it needs to be replaced according to requirements.

In detail, in one embodiment, the first circuit board 12 may be provided with only the first electrical connector 121 or only the second electrical connector 122. Therefore, when the first circuit board 12 disposed within the casing 11 is provided with only the first electrical connector 121, only the first type of replaceable power module 13 (power supply 131) may be correspondingly inserted; conversely, when the first circuit board 12 is provided with only the second electrical connector 122, only the second type of replaceable power module 13′ (power cable assembly 132) may be correspondingly inserted. Therefore, when replacing with different replaceable power modules 13, 13′, the first circuit board 12 also needs to be replaced accordingly.

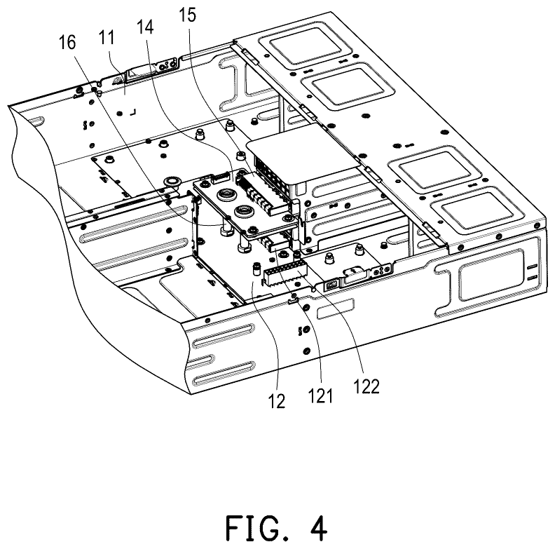

FIG. 4 is a schematic diagram of the first electrical connector 121 and the second electrical connector 122 together disposed on the first circuit board 12. In another embodiment as shown in FIG. 4, the first electrical connector 121 and the second electrical connector 122 may also be together disposed on the first circuit board 12. In this embodiment, since the first electrical connector 121 and the second electrical connector 122 are together disposed on the first circuit board 12, it is only necessary to replace the replaceable power module 13, and there is no need to replace the first circuit board 12.

FIG. 5A to FIG. 5C are schematic diagrams of the server 1 with the second type of replaceable power module 13′ installed therein being assembled to the cabinet 2.

As shown in FIG. 5A and FIG. 5B, the cabinet 2 has multiple drawers 21, in which each drawer 21 may correspondingly accommodate one server 1. A power bus 22 is provided at the rear of the cabinet 2, wherein the length direction L2 of the power bus 22 is parallel to the height direction H of the cabinet 2.

Next, as shown in FIG. 5B and FIG. 5C, the server 1 using the second type of replaceable power module 13′ slides into the drawer 21, and the fixture 1323 correspondingly inserts into the power bus 22 and clamps the electrode 221 of the power bus 22.

The cabinet 2 using the power bus 22 as such a power distribution system is developed in response to current conditions to correspond to the use of the server 1 having a larger casing 11 dimension. In detail, the dimension of the casing 11 of the first server correspondingly provided with the power cable assembly 132 is larger than the dimension of the casing 11 of the second server correspondingly provided with the power supply 131.

In the present disclosure, by utilizing the replaceable power modules 13, 13′, the power cable assembly 132 may be installed in the second server having the casing 11 with a smaller dimension, thereby allowing the second server with the casing 11 with smaller dimension to be universally used in the cabinet 2 of the power distribution system corresponding to the first server. In order to support the second server with the casing 11 with smaller dimension, the cabinet 2 may further include a detachable bracket 23 that is selectively used in response to servers 1 of different specification dimensions, wherein the bracket 23 extends into the drawer 21 in the lateral direction of the drawer 21 of the cabinet 2.

In summary, the server of the present disclosure may be universally used in cabinets of different power distribution systems through the use of replaceable power modules.

Furthermore, the first type of replaceable power module is fixed in the casing utilizing a latch, while the second type of replaceable power module is fixed on the casing utilizing a limiting pin, therefore both types of replaceable power modules are assembled and/or disassembled through simple assembly methods without requiring the use of other hand tools, providing convenience for users.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A server, comprising:
a casing;
a first circuit board disposed within the casing, wherein the first circuit board comprises at least one of a first electrical connector and a second electrical connector; and
a replaceable power module adapted to be assembled to the casing from one side of the casing, wherein the replaceable power module is adapted to be electrically connected to the first electrical connector or the second electrical connector.

2. The server as claimed in claim 1, wherein the replaceable power module is a power supply electrically connected to the first electrical connector.

3. The server as claimed in claim 2, wherein the power supply comprises:
a main body;
a plug disposed on a first side of the main body;
a latch disposed on a second side of the main body, wherein the second side of the main body and the first side of the main body are two adjacent sides; and
a gold finger disposed on a third side of the main body, wherein the second side of the main body is located between the first side of the main body and the third side of the main body.

4. The server as claimed in claim 3, wherein the first electrical connector is a slot for the gold finger.

5. The server as claimed in claim 4, wherein a quantity of the power supply is 2 and stacked along a thickness direction of the casing, the server further comprising a second circuit board and a at least one supporting conductive post, the second circuit board is disposed on the first circuit board and has a third electrical connector, and the at least one supporting conductive post is electrically connected between the first circuit board and the second circuit board.

6. The server as claimed in claim 1, wherein the replaceable power module is a power cable assembly electrically connected to the second electrical connector.

7. The server as claimed in claim 6, wherein the power cable assembly comprises:
a carrier;
a transmission wire accommodated in the carrier, one end of the transmission wire having a fourth electrical connector adapted to mate with the second electrical connector; and
a fixture disposed on one side of the carrier, the fixture and the fourth electrical connector being located on opposite sides of the carrier.

8. The server as claimed in claim 7, wherein the power cable assembly further comprises a cable clip disposed in the carrier, adapted to clamp the transmission wire to limit a position of the transmission wire.

9. The server as claimed in claim 7, wherein the power cable assembly further comprises a limiting pin disposed on another side of the carrier, the another side of the carrier is connected to a side the fixture located, and the casing has a positioning hole, when the power cable assembly is inserted into the casing, the limiting pin correspondingly engages the positioning hole to fix a position of the power cable assembly in the casing.

10. The server as claimed in claim 9, wherein the limiting pin comprises a pin and a handle, the handle is linked with the pin, and the length of the pin protruding from the positioning hole can be changed by rotating the handle.
